(19) United States
(12) Patent Application Publication
(10) Pub. No.: US 2007/0193520 A1
(43) Pub. Date: Aug. 23, 2007

(54) Lift pin calibrator and method of setting position of lift pin using the same

(76) Inventor: Young-Do Kim, Yongin-si (KR)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/494,449

(22) Filed: Jul. 28, 2006

(30) Foreign Application Priority Data
Feb. 21, 2006 (KR) 2006-0016932

(51) Int. Cl. C23F 1/00; C23C 16/00

(52) U.S. Cl. 118/729; 156/345.54

(57) ABSTRACT

A lift pin calibrator and a method of using the same set the height and orientation of a lift pin relative to a substrate support plate having a bore in which the lift pin is raised and lowered. The lift pin calibrator has a contact body, a pressure member and a tubular alignment member that are disposed coaxially. A pressure transmitting portion of the pressure member extends into an upper portion of the alignment member and the contact component extends through the pressure member so that an end of the contact component is left exposed by the pressure member. An outer diameter of the pressure transmitting portion of the pressure member is greater than an inner diameter of the alignment member. An extension of the alignment member is inserted into a bore of the substrate support plate. The pressure transmitting portion of the pressure member is forced into the alignment member to expand the alignment member and hold it in place. The lower end of a contact component is set at a predetermined height above the upper surface of the substrate support plate. The lift pin is raised via an elevating structure and into the extension of the alignment member until the top of the lift pin contacts the contact component. Subsequently, the lift pin is fixed in place relative to the elevating structure.

### BACKGROUND OF INVENTION

1. Field of the Invention

The present invention relates to semiconductor device production equipment having a reaction chamber, a substrate support disposed in the reaction chamber, and lift pins for raising and lowering a substrate from and onto the substrate support. More particularly, the present invention relates to a method of and device for calibrating the lift pins.

2. Description of the Related Art

In general, semiconductor device production equipment includes a process chamber and a substrate transfer mechanism. The substrate transfer mechanism can load or unload a semiconductor substrate into or from the process chamber. A substrate support and lift pins are disposed within the process chamber. The lift pins receive a substrate to be processed from the transfer mechanism and the transfer mechanism removes a processed substrate from the lift pins. Also, the lift pins are vertically movable through bores in a plate of the substrate support. Specifically, the lift pins are raised or lowered relative to the upper surface of the substrate support plate to position the semiconductor substrate on the substrate support or to remove the semiconductor substrate from the substrate support before or after the substrate is processed in the reaction chamber. Therefore, the lift pins and the substrate transfer mechanism can smoothly exchange an unprocessed semiconductor substrate for a processed semiconductor substrate in the reaction chamber.

However, the lift pins may become incorrectly positioned with respect to the substrate support plate after the semiconductor production equipment is cleaned. In particular, the upper surface of each lift pin may become skewed with respect to the upper surface of the substrate support plate. Thus, the upper surfaces of the lift pins will protrude by different amounts from the upper surface of the substrate support plate. If the lift pins in this state are left unchecked, the semiconductor substrate will not be properly transferred to or from the substrate support by the lift pins.

A method of setting lift pins in their proper position is disclosed in Korean Patent No. 489484 to Hee Young KANG et al. The method of KANG et al. comprises using a jig for the lift pins. The jig is disposed on a central region of the substrate support plate and includes a fixing part, a body and a rod that are disposed vertically one atop the other.

The rod extends from the top of the body over the center of the substrate support plate to the side of the lift pin. The body rests on the substrate support plate. The fixing part is inserted into a jig mounting recess in the center of the substrate support plate. The rod thus can be used to discern the distances of the lift pins relative from the center of the substrate support plate.

However, this method only allows for the positions of the lift pins relative to the center of the substrate support to be calibrated. That is, the prior art method does not allow for the inclination or orientation of the lift pins relative to the upper surface of the substrate support plate to be calibrated. The prior art method also does not allow for the height to which the lift pins are raised above the upper surface of the substrate support plate to be calibrated either.

### SUMMARY OF THE INVENTION

Therefore, an object of the present invention is to provide a lift pin calibrator by which a lift pin can be set in a proper position relative to a substrate support plate.

Another object of the present invention is to provide a method of calibrating a lift pin such that the lift pin is set at a proper position relative to a substrate support plate.

In accordance with the present invention, there is provided a lift pin calibrator and a method of using the same by which both the height and orientation of a lift pin relative to a substrate support plate can be set.

According to one aspect of the present invention, there is provided a lift pin calibrator comprising an upper unit including an upper housing and a contact component supported by the upper housing, and lower unit including a lower housing and a tubular alignment member disposed in the lower housing. The contact component extends into the upper housing and is supported by the, e.g., threaded to, the upper housing so as to be vertically movable relative to the upper housing. The tubular alignment member of the lower unit is disposed coaxially with the contact component.

According to another aspect of the present invention, the lift pin calibrator also includes an intermediate unit disposed on the lower unit and on which the upper unit is disposed. The intermediate unit includes an intermediate housing covered by the housing of the upper unit, and a pressure member extending into the intermediate housing and supported by, e.g., threaded to, the intermediate housing so as to be vertically movable relative to the intermediate housing. The pressure member has a pressure transmitting portion at a lower end thereof, and a through-hole in which the contact component is received such that the pressure member is vertically movable relative to the contact component. and a lower end of the contact component is left exposed by the pressure member.

The pressure transmitting portion of the pressure member extends into the tubular alignment member. Thus, the lower end of the contact component is also left exposed by the alignment member. An outer diameter of the pressure transmitting portion of the pressure member is larger than an inner diameter of the tubular alignment member.

According to another aspect of the present invention, there is provided a method of calibrating a lift pin of a substrate processing apparatus which begins by fixing a tubular alignment member having an extension in place relative to a substrate support plate with the extension aligned with a bore of the substrate support plate. Preferably, the extension has an inner diameter corresponding to the diameter of the lift pin. Also, the lower end of a contact component is set at a predetermined height above the upper surface of the substrate support plate as disposed coaxially with the tubular alignment body. Subsequently, the lift pin is raised via an elevating structure and into the extension of the alignment member and until the top of the lift pin contacts the lower end of the contact component. Next, the lift pin is fixed in place relative to a lift body of the elevating structure such that the lift pin can not move vertically relative to the lift body

### BRIEF DESCRITPTION OF THE DRAWINGS

The above and other objects, features and advantages of the present invention will become more apparent to those of ordinary skill in the art by referring to the detail description of the preferred embodiments thereof that follows as made with reference to the attached drawings in which:

FIG. 1 is an exploded sectional view of a lift pin calibrating device according to the present invention;

FIG. 2 is sectional view of the lift pin leveling calibrating device in an assembled state;

FIGS. 3 through 8 are sectional views for use in explaining a method of set the position of a lift pin using the lift pin calibrating device according to the present invention; and

FIG. 9 is a plan view of lift pins positioned relative to a substrate support according to the method of the present invention shown in FIGS. 3 through 8.

### BRIEF DESCRIPTION OF THE PREFERRED EMBODIMENTS

The preferred embodiments of the present invention will now be described more fully hereinafter with reference to the accompanying drawings. Note, like reference numbers are used to designate like elements throughout the drawings.

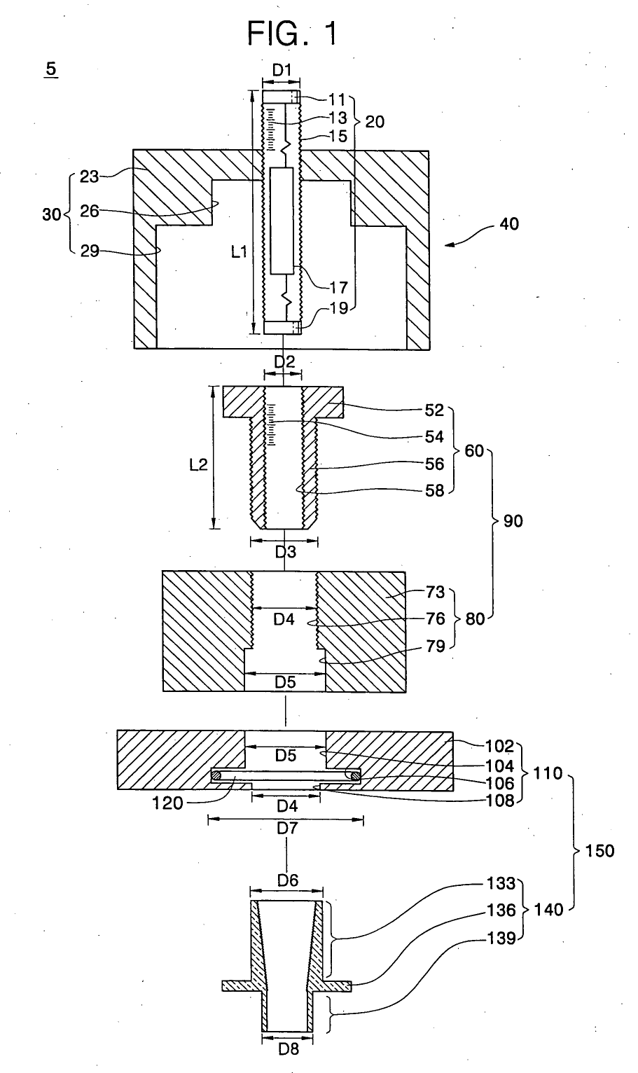

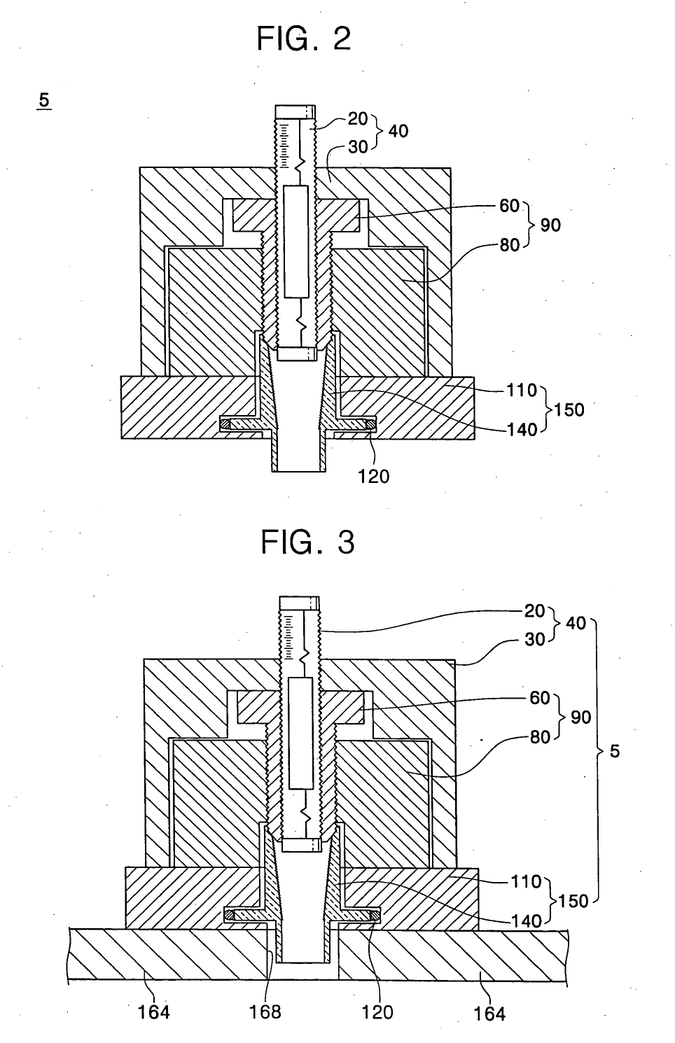

Referring first to FIGS. 1 and 2, a lift pin calibrator 5 comprises an upper adjustment unit 40, an intermediate adjustment unit 90, and a lower adjustment unit 150. The lower adjustment unit 150 is disposed below the upper and intermediate adjustment units 40 and 90. The intermediate adjustment unit 90 is enclosed by the upper adjustment unit 40.

The upper adjustment unit 40 includes an upper housing 30 and a contact component 20. The contact component 20 extends through the upper housing 30 and is supported by the upper housing 30 so as to be vertically movable relative to the upper housing 30. To this end, the contact component 20 is threaded to the upper housing 30.

The contact component 20 has a predetermined outer diameter D1 and a predetermined length L1. Also, the contact component 20 is made up of a light emitter 11, a contact measurement scale 13, a threaded measurement rod 15 whose outer diameter is D1, an oscillation circuit 17, and a contact 19. The light emitter 11 and contact 19 are disposed at upper and lower ends of the measurement rod 15, respectively. The oscillation circuit 17 is located in the measurement rod 15 and is electrically connected with the light emitter 11 and contact 19. The contact measurement scale 13 is located on the measurement rod 15, and indicates the position of the measurement rod 15 relative to (the (upper surface of) the upper housing 30. However, the contact 19, oscillation circuit 17 and light emitter 11 may be omitted. In this case, the contact component 20 is made up of only the contact measurement scale 13 and measurement rod 15.

The upper housing 30 has an upper body section 23, a receiving section 26, and a fixing section 29. The receiving section 26 and fixing section 29 extend perpendicular to the upper body section 23. Also, the receiving section 26 and fixing section 29 have different inner diameters. However, the receiving and fixing sections 26 and 29 may have the same inner diameter. In any case, the contact component 20 extends into the receiving section 26 and fixing section 29 and is engaged with (threaded to) and supported by the upper body section 23.

1. The intermediate adjustment unit 90 is made up of a pressure member 60 and an intermediate housing 80. The intermediate housing 80 is covered by the upper housing 30, as shown in FIG. 2. The pressure member 60 extends through the intermediate housing 80 and is supported so as to be vertically movable in the intermediate housing 80. To this end, the pressure member 60 is threaded to the intermediate housing 80 as well as to the contact component 20, as shown in FIG. 2.

The pressure member 60 has a predetermined length L2 that is preferably less than the length L1 of the contact component 20. The pressure member 60 has a pressure generating portion 52, a pressure measurement scale 54, a pressure transmitting portion 56 integral with the pressure generating portion 52, and through-hole 58 forming a female thread. The through-hole 58 thus extends through the pressure generating portion 52 and the pressure transmitting portion 56. Also, the through-hole 58 has a predetermined diameter D2 that is greater than the diameter D1 of the contact component 20. The pressure transmitting portion 56 has a predetermined outer diameter D3. The pressure measurement scale 54 can be located on the pressure transmitting portion 56, or on both the pressure generating portion 52 and the pressure transmitting portion 56 of the pressure member 60.

The intermediate housing 80 comprises an intermediate body 73 having an alignment hole 76 and a fixing hole 79 extending therethrough. Preferably, the alignment hole 76 and fixing hole 79 have different diameters D4 and D5, respectively. The intermediate body 73 is received in the fixing section 29 of the upper housing 30, as shown in FIG. 2. In this state, the pressure transmitting portion 56 of the pressure member 60 extends through the alignment hole 76 while in contact with the body 73 of the intermediate housing 80. More specifically, the alignment hole 76 defines a female thread and the pressure transmitting portion 56 of the pressure member 60 is thereby threaded to the body 73 of the intermediate housing 80. Thus, the pressure transmitting portion 56 is vertically movable in the body 73. Furthermore, the pressure generating portion 52 of the pressure member 60 is situated in the receiving section 26 of the upper housing 30 as interposed between the upper body section 23 of the upper housing 30 and the intermediate housing 80, as shown in FIG. 2.

Finally, the lower adjustment unit 150 is made up of a tubular alignment member 140 and a lower housing 110. The lower housing 110 is disposed below and in contact with the upper and intermediate housings 30 and 80. The upper and intermediate housings 30 and 80 can be fixed to the lower housing 110 using a jig member comprising a clamp (not shown). The alignment member 140 is received in the fixing hole 79 of the intermediate housing 80 and in the lower housing 110 and extends coaxially with the contact component 20 and pressure member 60. Preferably, the alignment member 140 is of an elastic material. Also, the alignment member 140 is threaded onto the pressure body 60. Preferably, the contact component 20 protrudes from the pressure member 60 into the alignment member 140, as best shown in FIG. 2.

The lower housing 110 has a lower body 102 through which a fixing alignment hole 104, an extension hole 106, and an extension alignment hole 108 extend in the foregoing sequence. Preferably, the diameters D5 and D4 of fixing alignment hole 104 and extension alignment hole 108 are different from each other. However, the diameter D5 of the fixing alignment hole may be the same as the diameter D4 of the extension alignment hole 108. The diameter D7 of the extension hole 106 is preferably greater than that of each of the extension alignment hole 108 and fixing alignment hole 104. Also, the fixing alignment hole 104 is located below and is open to the fixing hole 79 of the intermediate body 73. Preferably, the fixing hole 79 and fixing alignment hole 104 have the same diameter D5.

The alignment member 140 has an expansion portion 133, a flange 136, and an extension 139. The expansion portion 133 and extension 139 are situated on opposite sides of the flange 136, respectively. Preferably, the outer diameter D6 of the expansion portion 133 is greater than the outer diameter D8 of the extension 139. However, the outer diameters D6 and D8 of the expansion portion 133 and the extension 139 may be equal. Furthermore, the outer diameters D6 and D8 of the expansion portion 133 and extension 139 are preferably less than the diameters D5 and D4 of the fixing alignment hole 104 and extension alignment hole 108, respectively. Preferably, the outer diameter of the flange 136 is less than the diameter D7 of the extension hole 106.

The expansion portion 133, the flange 136 and the extension 139 are received in the fixing alignment hole 104, the extension hole 106 and the extension alignment hole 108 of the housing 110, respectively, as shown in FIG. 2. In this state, the extension 139 protrudes from the lower body 102 through the extension alignment hole 108. In addition, the tubular alignment member 140 has a tapered hole that defines a female thread within the expansion portion 133 and by which the expansion portion 133 is threaded onto the pressure member 60.

Furthermore, an elastic member 120 is disposed in the extension hole 106 so as to be interposed between the flange 136 of the alignment body 140 and the body 102 of the lower housing 110, as shown in FIG. 2. The elastic member 120 may comprise a spring. The flange 136 retains the alignment member 140 in the housing 110.

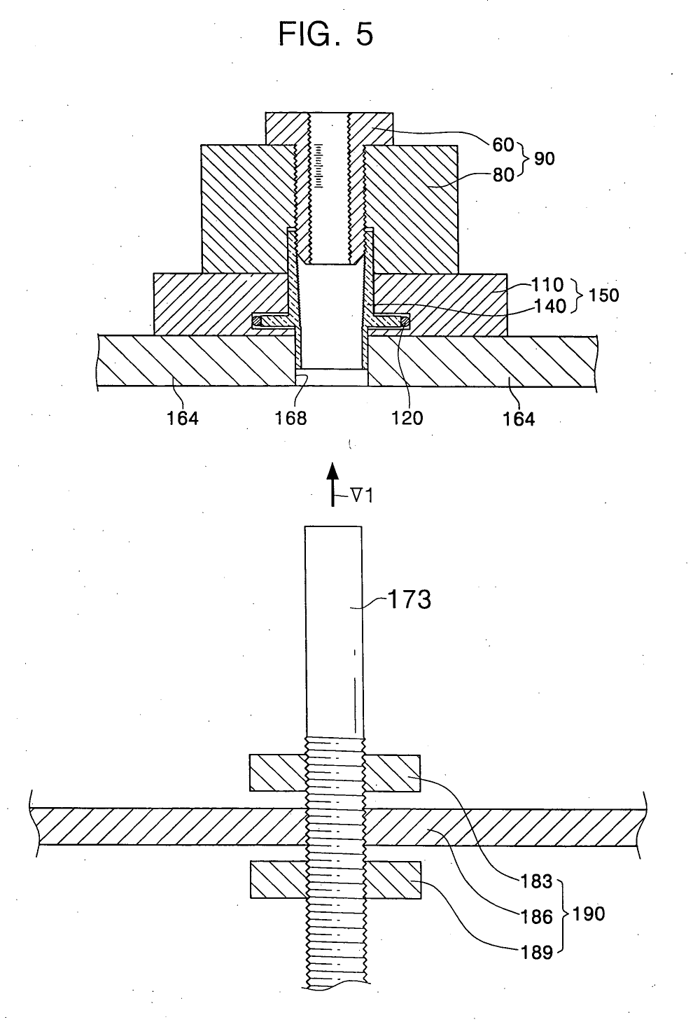

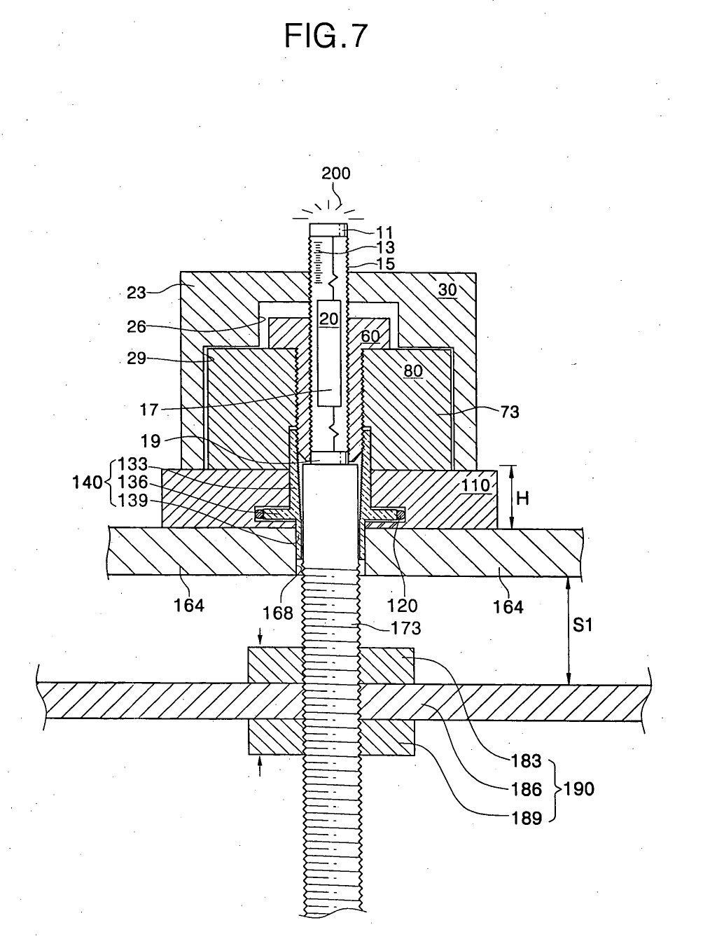

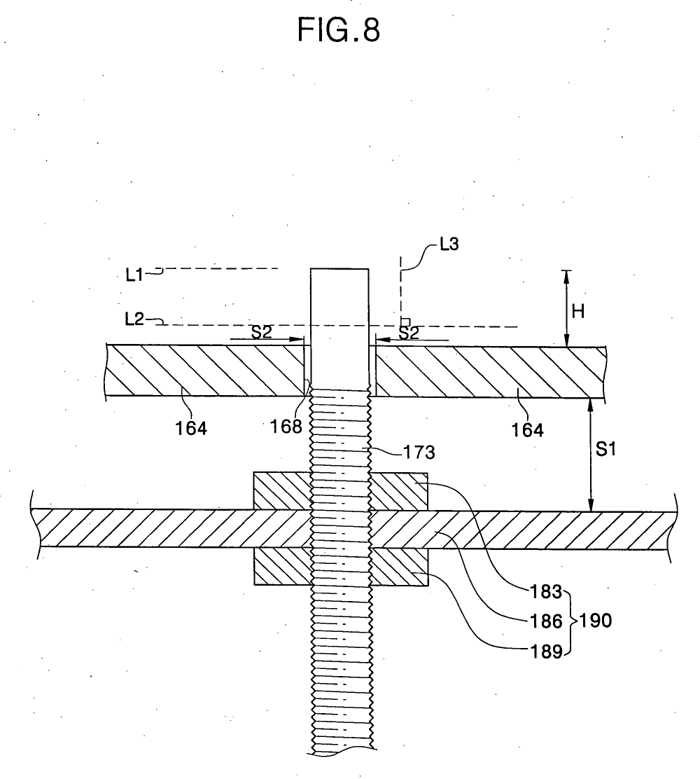

A method of aligning a lift pin using the above-described lift pin calibrator according to the present invention will be described below with additional reference to the FIGS. 3 through 8.

First, as shown in FIG. 3, the lift pin calibrator 5 is set on a substrate support plate 164. The substrate support plate 164 has a lift pin bore 168. At this time, the alignment body 140 is inserted into the bore 168 and thus, horizontal movement of the lift pin calibrator 5 is restricted by the bore 168. Accordingly, the lower, intermediate and upper housings 110, 80 and 30 are stacked on the substrate support plate 164 in that order. This method can also be applied to align a number of lift pins at a time. In this case, the same number of lift pin calibrators 5 as there are bores 168 are disposed on the substrate support plate 164. Also, the lift pin calibrators 5 may be connected to one another.

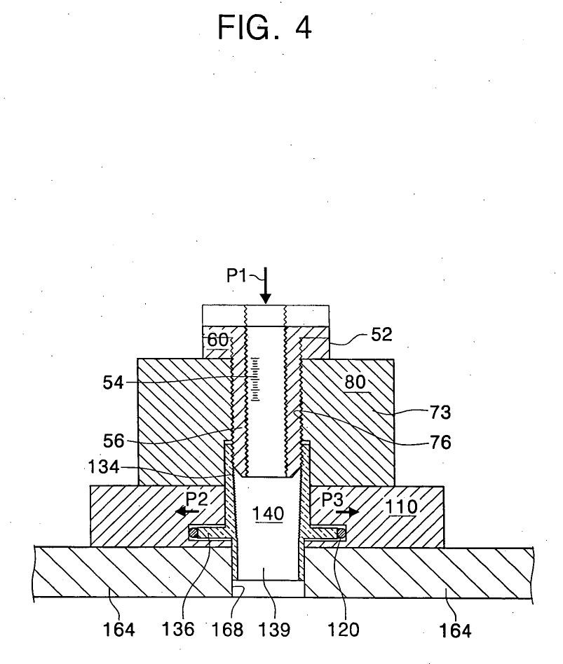

Referring to FIGS. 1, 2 and 4, the upper adjustment unit 40 (contact component 20 and upper housing 30) is removed from the intermediate and lower housings 80 and 110. As a result, the pressure member 60 is exposed. Then, the pressure member 60 is rotated in a direction that moves the pressure member 60 vertically toward the lower housing 110. The vertical movement of the pressure member 60 exerts pressure P1 on the alignment member 140. More specifically, the pressure generating portion 52 of the pressure member 60 is advanced into the alignment member 140 from the position shown in FIG. 3 to the position shown in FIG. 4. The alignment member 140 distributes the pressure P1. As a result, the alignment member 140 expands in the intermediate and lower housings 80 and 110 and exerts pressure P2, P3 on the inner walls of the housings 80 and 110.

That is, the expansion portion 133 of the alignment member 140 is brought into contact with the walls of the intermediate body 73 and lower body 102 which define the fixing hole 79 and fixing alignment hole 104, respectively. The flange 136 is also moved towards the side walls that define the extension hole 106, thereby compressing the elastic member 120. The extension 139 is brought into contact with the side wall of the lower body 102 that defines the extension alignment hole 108.

Referring to FIGS. 1, 2 and 5, a lift pin 173 and an elevating structure 190 are disposed below the substrate support plate 164. The elevating structure 190 includes a descent adjuster 183, a lift body 186, and an ascent adjuster 189. The elevating structure 190 and the lift pin 173 are threaded to each other. At this time, the lift pin 173 is vertically aligned with the bore 168 of the substrate support plate 164. Then, the elevating structure 190 raises the lift pin 173 by an initial amount towards the substrate support plate 164, as indicated by V1. At this time, the lift pin 173 is not clamped to the lift body 186 by the descent adjuster 183 and ascent adjuster 189, i.e., the lift pin 173 is supported by but is not fixed in place relative to the lift body 186.

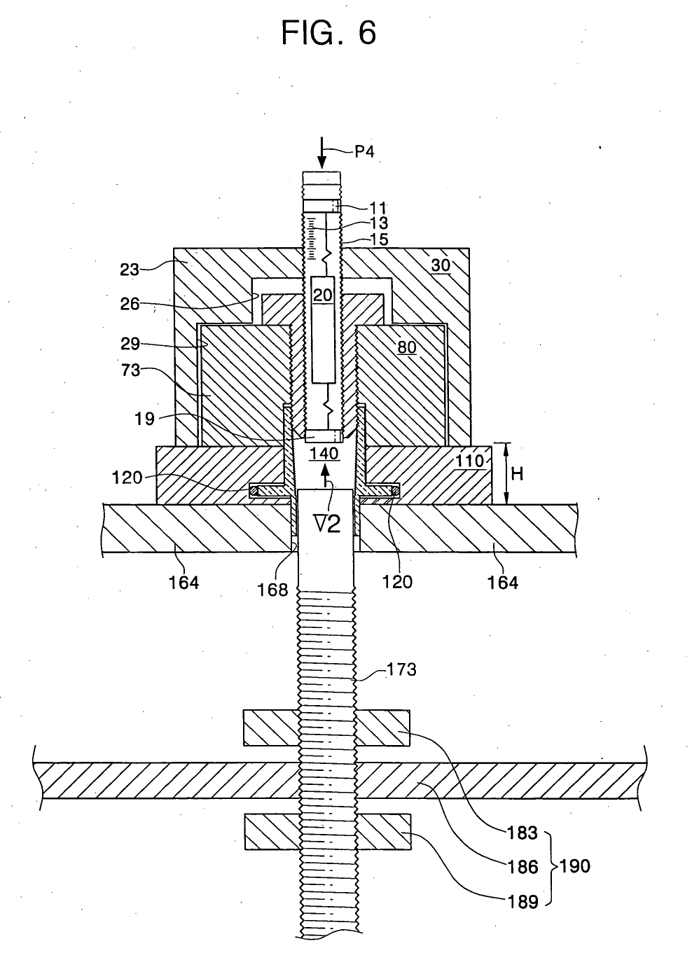

Referring to FIG. 6, the lift pin 173 is raised by the elevating structure 190 a secondary amount, as indicated by V2. At this time, the lift pin 173 is inserted into the extension 139 of the alignment member 140 through the bore 168 of the substrate seat 164. However, the lift pin 173 is still not fixed in place relative to the lift body 186.

Next, the upper housing 30 is placed on the intermediate unit 90 so as to enclose the intermediate housing 80. In particular, the fixing section 29 of the upper housing 30 encloses the intermediate housing 80. At the same time, the receiving section 26 of the upper housing 30 encloses the pressure generating portion 52 of the pressure member 60. Then, the contact component 20 is rotated relative to the upper housing 30 by an amount necessary to move the contact component 20 vertically (as indicated by arrow P4) within the through-hole 58 of the pressure body 60 until the contact component 20 is located a predetermined height H above the upper surface of the substrate support plate 164. To this end, the contact measurement scale 13 can be read as the contact component 20 is being adjusted to ensure that the contact component 20 is located at the correct height H above the upper surface of the substrate support 164.

Referring to FIGS. 1, 2 and 7, the elevating structure 190 continues to be raised until the lift body is brought to a predetermined distance S1 from the substrate support plate 164. Also, the lift pin 173 is adjusted until the top of the lift pin 173 contacts the contact component 20. As soon as the lift pin 173 impacts the contact 19 of the contact component 20, the oscillation circuit 17 converts the physical impact into an electrical signal and transmits the electrical signal to the light emitter 11. The electrical signal is converted into light by the light emitter 11. Thus, the contact component 20 emits light as soon as the lift pin 173 is raised up against the contact component 20.

Thus, the top of the lift pin 173 is at the predetermined height H from the upper surface of the substrate support 164 once the light emitter 11 emits light. Then, the lift pin 173 is clamped to the lift body 186 using the descent adjuster 183 and ascent adjuster 189, thereby setting the lift pin 173 at the proper level in relation to the substrate support plate 164. At this time, the lift body 186 and the substrate support 164 remain spaced apart from each other by the predetermined distance S1.

Subsequently, the upper unit 40 is removed from the intermediate and lower housings 80 and 110. Then, the pressure member 60 is withdrawn from the tubular alignment member 140 such that the alignment member 140 contracts and thereby becomes spaced apart from the intermediate and lower housings 80 and 110 and the substrate support plate 164. Accordingly, the intermediate housing 80, the lower housing 110 and the alignment member 140 can be separated from the substrate support plate 164.

Referring to FIGS. 1, 2 and 8, the lift pin 173 and substrate support plate 164 are properly configured once the alignment member 140 has been removed from the substrate support 164. In particular, the upper surface of the lift pin 173 is parallel to the upper surface of the substrate support plate 164, as represented by horizontal lines L1 and L2 in the figure. A sidewall of the lift pin 173 is perpendicular to the upper surface of the substrate support plate 164, as represented by vertical line L3 and horizontal line L2 in the figure.

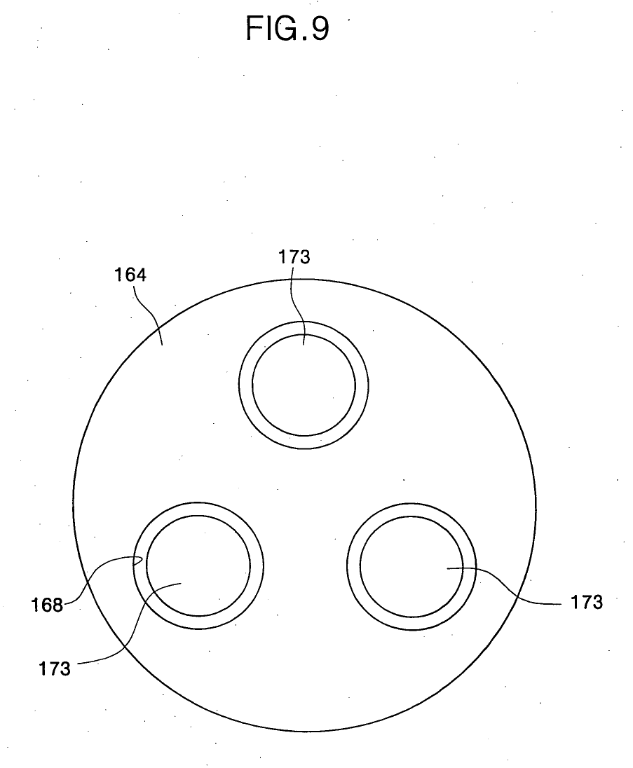

Also, the sidewall of the lift pin 173 is spaced apart from the substrate support plate 164 within the bore 168 by a constant interval S2 in the circumferential direction of the lift pin 173. The lift pins 173 and the bores 168 appear as shown in FIG. 9 once the lift pins 173 is properly aligned with the bores 168 in this way. As mentioned previously, each of the lift pins 173 can be aligned with their respective bores 168. In addition, as was mentioned above, the tops of the lift pins 173 will be set at the same level above the upper surface of the substrate support plate 164. In other words, the top of each of the lift pins 173 will be located at a predetermined height H above the upper surface of the substrate support 164 when the elevating structure is brought to its uppermost position. At the same time, the substrate support plate 164 will be spaced a predetermined distance S1 from the lift body 186 of the elevating structure 190.

Also, at this time, each lift pin 173 can be brought into contact with a digital instrument (not shown) or the like to check the distance by which the lift pin 173 protrudes from the upper surface of the substrate support plate 164. Furthermore, the interval between each lift pin 173 and the inner wall of the substrate support plate 164 that defines the bore 168 through which the lift pin 173 passes can be measured using an appropriate digital instrument or the like. That is, the configuration, i.e., the orientation and level of the lift pin 173 relative to the substrate support plate 164, can be checked after the calibrator(s) 5 is/are removed from the substrate support plate 164.

As mentioned above, the present invention provides a calibrator for and a method of setting the level and orientation of a lift pin relative to a substrate support. Accordingly, the present invention can ensure that a semiconductor substrate has a good alignment with the substrate support plate and/or a substrate transfer mechanism during a semiconductor device production process or the like.

Finally, although the present invention has been described above in connection with the preferred embodiments thereof, the present invention is not so limited. Rather, the true spirit and scope of the invention is defined by the appended claims.

What is claimed is:

1. A lift pin calibrator comprising:
an upper unit including an upper housing, and a contact component extending into the upper housing and supported by the upper housing so as to be vertically movable relative to the upper housing;
an intermediate unit on which the upper unit is disposed, the intermediate unit including an intermediate housing covered by the housing of the upper unit, and a pressure member extending into the intermediate housing and supported by the intermediate housing so as to be vertically movable relative to the intermediate housing, the pressure member having pressure transmitting portion at a lower end thereof, and a through-hole in which the contact component is received such that the pressure member is vertically movable relative to the contact component, and whereby a lower end of the contact component is left exposed by the pressure member; and
a lower unit including a lower housing, and a tubular alignment member disposed in the lower housing as disposed coaxially with the contact component and the pressure member, the pressure transmitting portion of the pressure member extending into the tubular alignment member, whereby the lower end of the contact component is also left exposed by the alignment member, and an outer diameter of the pressure transmitting portion of the pressure member being larger than an inner diameter of the tubular alignment member.

2. The lift pin calibrator according to claim 1, wherein the contact component includes a measurement rod, a light emitter and a contact that are disposed at upper and lower ends of the measurement rod, respectively, an oscillation circuit disposed in the measurement rod and electrically connected with the light emitter and the contact so as to transmit a signal to the light emitter when the contact receives an impact, and a contact measurement scale on the measurement rod whereby the position of the contact component relative to the upper housing can be discerned.

3. The lift pin calibrator according to claim 1, wherein the pressure member has a pressure generating portion at an upper end thereof, the upper housing includes an upper body section engaged with the contact component, a receiving section in which the pressure generating portion of the pressure body is received, and a fixing section in which the intermediate housing is received.

4. The lift pin calibrator according to claim 3, wherein the pressure member has a pressure measurement scale on the outside thereof, whereby the position of the pressure member relative to the tubular alignment member can be discerned.

5. The lift pin calibrator according to claim 3, wherein the intermediate housing comprises an intermediate body through which an alignment hole and a fixing hole extend coaxially, the diameter of the fixing hole is greater than that of the alignment hole, the pressure transmitting portion of the pressure member extends through the alignment hole, and the alignment member has an expansion portion at an upper end thereof, the expansion portion received in the fixing hole.

6. The lift pin calibrator according to claim 5, wherein the pressure transmitting portion of the pressure member engages the intermediate body within the alignment hole.

7. The lift pin calibrator according to claim 6, wherein the lower housing comprises a lower body through which a fixing alignment hole, an extension hole, and an extension alignment hole extend coaxially, the extension hole has a diameter greater than that of each of the extension alignment hole and the fixing alignment hole, the alignment member includes an extension and a flange interposed between the expansion portion and the extension, the expansion portion being received in the fixing alignment hole, the flange being received in the extension hole, and the extension being received in the extension alignment hole.

8. The lift pin calibrator according to claim 7, wherein the fixing hole and the fixing alignment hole have the same diameter, and the extension protrudes from the lower housing through the extension alignment hole.

9. The lift pin calibrator according to claim 7, wherein the expansion portion of the tubular alignment member has a frustum-shaped inner wall surface whose diameter in cross section decreases in an axial direction of the alignment member towards the flange.

10. The lift calibrator according to claim 8, wherein the lower unit further comprises an elastic member interposed between the flange and the body of the lower housing.

11. The lift pin calibrator according to claim 1, wherein the contact component is threaded to the housing of the upper unit, and the pressure member is threaded to the housing of the intermediate unit.

12. A lift pin calibrator comprising:
an upper unit including an upper housing, and a contact component extending into the upper housing and supported by the upper housing so as to be vertically movable relative to the upper housing; and
a lower unit on which the upper unit is disposed, the lower unit including a lower housing, and a tubular alignment member disposed in the lower housing as disposed coaxially with the contact component, wherein the lower end of the contact component is exposed through the alignment member.

13. The lift pin calibrator according to claim 12, wherein the contact component includes a measurement rod, a light emitter and a contact that are disposed at upper and lower ends of the measurement rod, respectively, an oscillation circuit disposed in the measurement rod and electrically connected with the light emitter and the contact so as to transmit a signal to the light emitter when the contact receives an impact, and a contact measurement scale on the measurement rod whereby the position of the contact component relative to the upper housing can be discerned.

14. The lift pin calibrator according to claim 12, wherein the lower housing comprises a lower body through in which an extension hole and an extension alignment hole extend coaxially, the extension hole has a diameter greater than that of the extension alignment hole, the alignment member includes an extension and a flange, the flange being received in the extension hole, and the extension being received in the extension alignment hole.

15. The lift pin calibrator according to claim 14, wherein the extension protrudes from the lower housing through the extension alignment hole.

16. The lift calibrator according to claim 14, wherein the lower unit further comprises an elastic member interposed between the flange and the body of the lower housing.

17. The lift pin calibrator according to claim 1, wherein the contact component is threaded to the housing of the upper unit.

18. A method of calibrating a lift pin of a substrate processing apparatus which includes a process chamber, a substrate support plate disposed in the process chamber and having a bore extending therethrough, and elevating structure having a lift body that supports the lift pin such that lift pin is carried by and is vertically movable relative to the lift body, the elevating structure being vertically movable to selectively raise the lift pin out of the through-hole and retract the lift pin into the through-hole, the method comprising:
fixing a tubular alignment member having an extension in place relative to the substrate support plate with the extension aligned with the bore of the substrate support plate, and wherein the extension has an inner diameter corresponding to the diameter of the lift pin;
setting the lower end of a contact component at a predetermined height above the upper surface of the substrate support plate as disposed coaxially with the tubular alignment body;
subsequently raising the lift pin via the elevating structure and into the extension of the alignment member until the top of the lift pin contacts the lower end of the contact component;
subsequently fixing the lift pin in place relative to the lift body of the elevating structure such that the lift pin can not move vertically relative to the lift body.

19. The method of claim 18, wherein the fixing of the tubular alignment member in place relative to the substrate support plate includes inserting the extension thereof into the bore of the substrate support plate.

20. The method according to claim 18, wherein the physical impact of the lift pin on the lower end of the contact component generates an electrical signal, the electrical signal is transmitted to a light emitter, and the light emitter generates light upon receiving the electrical signal.

21. The method according to claim 18, wherein the fixing of the tubular alignment member in place comprises expanding the tubular alignment member outwardly against a housing in which the alignment member is received.

22. The method according to claim 18, wherein the lift pin has a thread and is threaded to the lift body of the elevating structure, and the fixing of the lift pin in place relative to the lift body of the elevating structure comprises rotating a descent adjuster threaded to the lift pin above the lift body to lower the descent adjuster into contact with the upper surface of the lift body, and rotating an ascent adjuster threaded to the lift pin below the lift body to raise the ascent adjuster into contact with the lower surface of the lift body while the lift body is at a predetermined distance from the substrate support plate.
